(19) United States
(12) Patent Application Publication
(10) Pub. No.: US 2011/0220174 A1
(43) Pub. Date: Sep. 15, 2011

(54) COMPACT PHOTOVOLTAIC DEVICE

(75) Inventors: Sio Kuan Lam, Sheung Shui (HK); Tao Pan, Shenzhen (CN)

(73) Assignee: Hong Kong Applied Science and Technology Research Institute Co. Ltd., New Territories (CN)

(21) Appl. No.: 12/721,207

(22) Filed: Mar. 10, 2010

(51) Int. Cl. H01L 31/052

(52) U.S. Cl. 136/246

(57) ABSTRACT

The subject matter disclosed herein relates to a photovoltaic device, and in particular, a multichannel photovoltaic device to concentrate incident light for electrical generation.

### FIELD

The subject matter disclosed herein relates to a photovoltaic device, and more particularly, to a multichannel photovoltaic device to concentrate incident light for electrical power generation.

### BACKGROUND

Though sunlight, the energy source of solar power generation, is virtually free and abundant, these benefits of sunlight may be offset by a relatively high expense associated with solar power generating photovoltaic (PV) cells. Also, corresponding to relatively low efficiency of such PV cells, a relatively large area may be occupied by PV cells in order to generate a desired amount of electrical power. Accordingly, improvements in efficiency of PV cells may lead to reduced cost for solar power generation and/or increased capacity to generate solar power.

### BRIEF DESCRIPTION OF THE DRAWINGS

Non-limiting and non-exhaustive embodiments will be described with reference to the following objects, wherein like reference numerals refer to like parts throughout the various objects unless otherwise specified.

FIG. 1 is a perspective view of a photovoltaic system, according to an embodiment.

FIG. 2 includes schematic side and perspective views of a photovoltaic system, according to an embodiment.

FIGS. 3-7 are perspective views of photovoltaic systems, according to embodiments.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, methods, apparatuses, or systems that would be known by one of ordinary skill have not been described in detail so as not to obscure claimed subject matter.

Reference throughout this specification to “one embodiment” or “an embodiment” may mean that a particular feature, structure, or characteristic described in connection with a particular embodiment may be included in at least one embodiment of claimed subject matter. Thus, appearances of the phrase “in one embodiment” or “an embodiment” in various places throughout this specification are not necessarily intended to refer to the same embodiment or to any one particular embodiment described. Furthermore, it is to be understood that particular features, structures, or characteristics described may be combined in various ways in one or more embodiments. In general, of course, these and other issues may vary with the particular context of usage. Therefore, the particular context of the description or the usage of these terms may provide helpful guidance regarding inferences to be drawn for that context.

Likewise, the terms, “and,” “and/or,” and “or” as used herein may include a variety of meanings that also is expected to depend at least in part upon the context in which such terms are used. Typically, “or” as well as “and/or” if used to associate a list, such as A, B or C, is intended to mean A, B, and C, here used in the inclusive sense, as well as A, B or C, here used in the exclusive sense. In addition, the term “one or more” as used herein may be used to describe any feature, structure, or characteristic in the singular or may be used to describe some combination of features, structures, or characteristics. Though, it should be noted that this is merely an illustrative example and claimed subject matter is not limited to this example.

Embodiments described herein include a photovoltaic (PV) device to convert light to electrical power using particular configurations of optical elements and PV elements. For example, one such PV device may comprise an array of light concentrators to collect and focus light and an array of light splitters to selectively reflect and transmit the collected and focused light. Such selectivity may be based, at least in part, on wavelength of the collected light. In detail, an array of light splitters may reflect light having a particular range of wavelengths and direct such reflected light to a first solar cell. The array of light splitters may transmit light having another particular range of wavelengths and direct such transmitted light to one or more second solar cells. Such an array of light splitters may be configured to direct such reflected light to converge to a region coincident with a location of the first solar cell. Such a location may be substantially equally distant from an array of light concentrators, for example. First and second solar cells may have operating wavelength ranges different from one another. Such a PV device may provide a number of benefits. For example, particular PV elements, hereinafter referred to as solar cells, may operate relatively efficiently only over particular ranges of wavelengths. In other words, different solar cells may operate most efficiently in different ranges of wavelengths. For example, a double junction (DJ) solar cell may operate most efficiently in a wavelength range from 880 nanometers (nm) to 1270 nm while a silicon solar cell may operate most efficiently in a wavelength range from 310 nm to 880 nm, though claimed subject matter is not limited in this respect. Because sunlight comprises a relatively wide bandwidth of wavelengths, it may be advantageous to utilize multiple types of solar cells to generate electrical power from light having different ranges of wavelengths. Accordingly, an embodiment of a PV device as described above, for example, may accommodate more than one type of solar cell, thereby increasing the PV device's wavelength range of operation.

Another benefit introduced by such a PV device is a compactness of the PV device that may be achieved by particular optical elements and/or particular configuration of such optical elements, as described in detail below. Yet another benefit may include the fact that such a PV device may operate using relatively small optical elements, which may be substantially less expensive than comparable larger-sized optics. Still another benefit may include the fact that heat generated in the course of operating particular types of solar cells may be relatively efficiently removed from a PV device via a structural element (e.g., a heat pipe) of the PV device, as described in detail below. In such a case, a PV device need not include portions whose single purpose is to remove heat. Accordingly, such a PV device may provide a number of benefits that address a desire for a relatively efficient, small-size solar power-generating device having a relatively low cost. Of course, benefits of such a PV device are not limited to those described above, and claimed subject matter is also not so limited.

In an embodiment, a method of producing a PV device, such as the embodiment of a PV device described above, for example, may comprise assembling an array of light concentrators to collect and/or focus light, such as sunlight. To operate in conjunction with such light collectors, an array of light splitters may be arranged to selectively reflect and transmit collected and/or focused light based, at least in part, on a wavelength of the light. The array of light splitters may be configured to direct reflected light to a first solar cell and to direct transmitted light to one or more second solar cells. First and second solar cells may have operating wavelength ranges different from one another. Additionally, reflected light may be collimated by a combination of the light concentrators and light splitters to converge to a region coincident with a location of the first solar cell. In one implementation, one or more second solar cells may be arranged about a central axis of the array of light concentrators and the array of light splitters. Such an arrangement may be substantially symmetrical about such an axis, for example.

In an embodiment, a method of operating a PV device, such as the embodiment of a PV device described above for example, may comprise collecting and/or focusing incident light and providing the collected and/or focused light to an array of light splitters. Such light splitters may reflect the light based, at least in part, on a wavelength of the light and to transmit the collected light based, at least in part, on said wavelength of said light. Reflected light may then be directed to converge to a region coincident with a location of a first solar cell, whereas transmitted light may be directed to one or more second solar cells. First and second solar cells may have operating wavelength ranges different from one another. Of course, such details of producing or operating a PV device are merely examples, and claimed subject matter is not so limited.

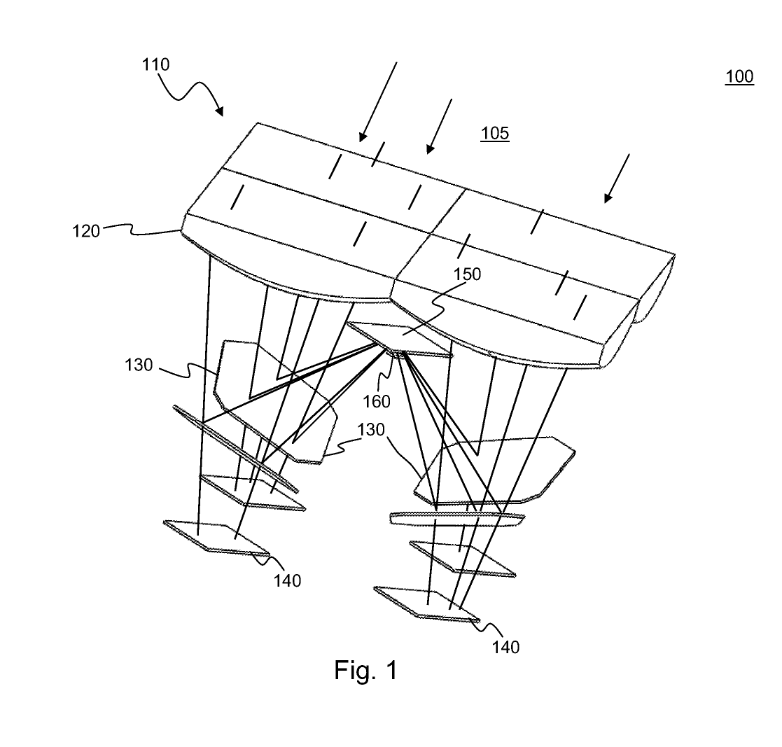

FIG. 1 is a perspective view of a photovoltaic device 100, according to an embodiment. Light 105, upon falling on an array 110 of light concentrators 120, may be focused and directed to an array of light splitters 130. Such light concentrators may comprise refractive lenses or a combination of refractive lens (e.g., compound lenses), and/or Fresnel lenses, just to name a few examples. Such light concentrators may have an associated focal length determining a distance at which light transmitting the light concentrators may be focused. Additionally, such light concentrators may have an associated numerical aperture (N.A.) determining an angle of convergence of light transmitting the light concentrators. Accordingly, such light concentrators may concentrate light by converging light at a particular angle and focused at a particular focal length. Optical elements downstream of such light concentrators may be arranged in view of a focal length and/or N.A. of the light concentrators, for example. An array of such light concentrators may comprise one or more light concentrators arranged in any number of possible patterns. In a particular example, such an array may comprise four light concentrators arranged in rows and columns, as described in further detail below. An ability to use an array of relatively small light concentrators as opposed to a single larger light concentrating element may be beneficial by reducing costs of PV device 100.

In an implementation, light splitters 130 may comprise an optical element that reflects light having a particular wavelength range while transmitting light having another particular wavelength range. Such light splitters may comprise an optical window (e.g., quartz) that includes multiple optical dielectric coatings on one or both sides of the window. Such an optical window need not have flat surfaces. Such coatings may reflect and/or transmit incident light based, at least in part, on the wavelength of the incident light. In one particular implementation, PV device 100 may comprise a light concentrator for every light splitter. In such a case, incident light 105 collected by a light concentrator 120 may direct converging light onto a corresponding light splitter 130. Light splitter 130 may then reflect a portion of the light to a first solar cell 160 and transmit another portion of the light to a second solar cell 140. As explained above, such portions may be determined by the wavelength of the light. Also, one or more minors may be placed between light splitters 130 and first and/or second solar cells in order to direct light to the solar cells. In PV device 100, for example, mirror 150 may be placed before first solar cell 160. Of course, such aspects and details of a PV device are merely examples, and claimed subject matter is not so limited.

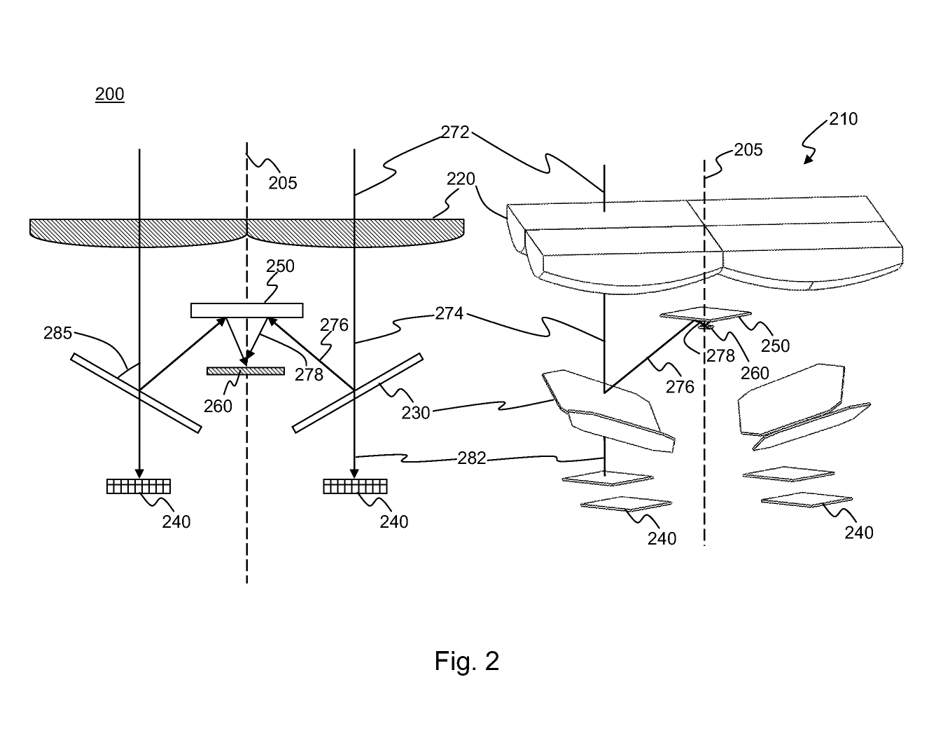

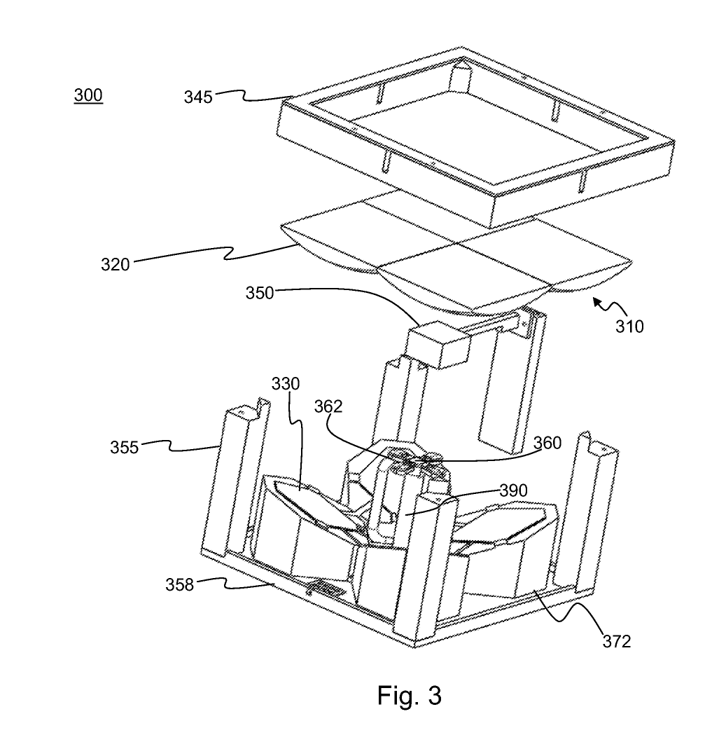

FIG. 2 includes schematic side and perspective views of a photovoltaic system 200, according to an embodiment. An array 210 of light concentrators 220 may receive incident light 272, which need not be perpendicularly incident on a surface of light concentrators 220, as shown in FIG. 2. Light 274 exiting (e.g., transmitting) light concentrators 220 may subsequently fall onto light splitters 230, which may be arranged substantially symmetrically about a central axis 205. Light concentrators 220 may also be arranged substantially symmetrical about central axis 205. In an implementation, central axis 205 may intersect a substantially central point of light concentrators 220 and a substantially central point of light splitters 230. Light splitters 230 may reflect a portion of light 274 having a particular range of wavelengths. Such reflected light 276 may be directed to a first solar cell 260, via mirror 250, by arranging an angle 285 of light splitters relative to central axis 205, for example. In such an implementation, an ability to adjust angle 285 may provide a benefit of simplifying a technique of focusing multiple beams of light (reflected from individual light splitters 230) onto first solar cell 260. To illustrate a particular example, angle 285 may comprise about 66 degrees, wherein at such an angle, a shape and size of a light spot falling onto first solar cell 260 may be adjusted to enhance light collimation in PV device 200. In particular, angle 285 at which individual light splitters maybe tilted may comprise substantially an angle in a range between 60 to 70 degrees from the central axis. A light splitter 230 at other angles, for example, may misdirect light 276 leading to only a relatively small portion of light 276 actually being received by first solar cell 260. Light 278 represents light reflected from mirror 250 and incident on first solar cell 260. Accordingly, angular adjustment of light splitters 230 may provide a technique for adjusting operating efficiency of PV device 200. Of course, for implementations involving optical elements (e.g., light concentrators) having different focal lengths than those of the examples above, angle 285 at which desirable optical alignment is achieved may also be different. A particular feature of PV device 200 is the fact that multiple light paths, or “channels”, as explained below, may be directed to converge onto first solar cell 260, which may comprise a single solar cell. As a result of such a convergence of multiple light paths onto a relatively small region comprising first solar cell 260, a relatively large amount of heat may collect at the first solar cell 260. Accordingly, first solar cell 260 may be mounted on or near a heat pipe (shown in FIGS. 3-5, for example) to conduct heat away from first solar cell 260, for example.

A portion of light 274 not reflected by light splitters 230 may be transmitted by light splitters 230. As discussed above, such transmitted light 282 may have a particular range of wavelengths different from that of reflected light 276. Transmitted light 282 may be directed to second solar cells 240, for example. A particular feature of PV device 200 is the fact that a single second solar cell 240 may be arranged to receive light from a single light path. As a result of such a one-to-one correspondence, heat collected at second solar cells 240 may be relatively evenly distributed among a relatively large area occupied by the multiple second solar cells 240. Accordingly, PV device 200 may avoid problems arising because of excess heat collection at solar cells, for example.

In a particular implementation, first solar cell 260 may comprise a DJ solar cell, while second solar cells 240 may comprise a silicon solar cell, though claimed subject matter is not so limited. Any of a number of types of solar cells may be used, and a selection of particular solar cells may be based, at least in part, on operating wavelength ranges of different types of solar cells. Such wavelength ranges and/or placement of particular solar cells may be coordinated with spectral properties of light splitter 230. For example, placement of a solar cell having a particular operating wavelength range may depend on whether light splitter 230 directs light having the particular wavelength range to where the solar cell is to be placed.

In an embodiment, an optical path comprising a light concentrator 220, a light splitter 230, a second solar cell 240, and light path 276 and 278 may be referred to as a light channel. Though PV device 200 is shown in FIG. 2 as having four light channels, other numbers of light channels are possible, and claimed subject matter is not so limited. Also, such light channels need not be symmetrically arranged about central axis 205, though such an arrangement may lead to a relatively compact PV device. Such a symmetrical arrangement may also allow optical elements in the respective channels to be substantially similar (e.g., similar focal length, N.A., and so on). For example, a nonsymmetrical arrangement of light channels about central axis 205 may lead to imbalanced light channels that may be relatively difficult to optically align and/or focus. Similarly, a position of first solar cell 260 relative to other portions of PV device 200 may also lead to a relatively compact PV device. In a particular implementation, such a position of first solar cell 260 may comprise a central region among an array of light splitters 230 on central axis 205, for example. Of course, such aspects and details of a PV device are merely examples, and claimed subject matter is not so limited.

FIG. 3 is an exploded perspective view of a photovoltaic device 300, according to an embodiment. An array 310 of light concentrators 320 may be arranged to receive incident light through top frame 345 that is part of a supporting structure of PV device 300. For example, such a supporting structure may include a bottom frame 358 and supporting posts 355. Light splitters 330 may be positioned to receive light transmitted through array 310. A particular number of light splitters 330 to correspond to the number of light concentrators 320 may be arranged symmetrically about an axis perpendicularly intersecting a center of array 310, such as central axis 205 shown in FIG. 2, for example. Light concentrators 320 may also be arranged symmetrically about such an axis. As explained above, light splitters 330 may reflect a portion of incident light having a particular range of wavelengths. Such reflected light may subsequently be directed to a first solar cell 360, via mirror 350. Connectors 362, such as solder balls, pins, leads, and so on, may comprise electrically and/or mechanical connectors to connect external components (not shown) to first solar cell 360, for example. In one particular implementation, light splitters 330 may be mounted on a portion 372 of the supporting structure of PV device 300 so that the light splitters may be rotationally adjustable about one or more axes to adjust a tilting angle of the light splitters. Such adjustability may provide a technique to finely adjust collimation of light from light splitters 330 to first solar cell 360, for example. As explained above, operating efficiency of PV device 300 may be at least partly based on the effectiveness of light collimation among the optical elements of PV device 300. In an implementation, tilting angle of light splitters and/or light collimation may depend, at least in part, on a focal length of light concentrators 320.

Because multiple channels of light may be directed to a single first solar cell 360, a relatively large amount of heat may collect at the first solar cell. Accordingly, first solar cell 360 may be mounted on a central supporting structure 390 comprising a heat pipe to conduct heat away from first solar cell 360, for example. In one implementation, such a heat pipe may be mechanically attached to a supporting structure of PV device 300. A heat pipe need not be the only structural element supporting first solar cell 360. Central supporting structure 390 may provide a benefit of being relatively easily configured to avoid blocking sunlight or other light within PV device 300. For example, central supporting structure 390 may comprise a relatively straight, vertical structure to support first solar cell 360. Of course, such a heat pipe and other aspects and details of a PV device are merely examples, and claimed subject matter is not so limited.

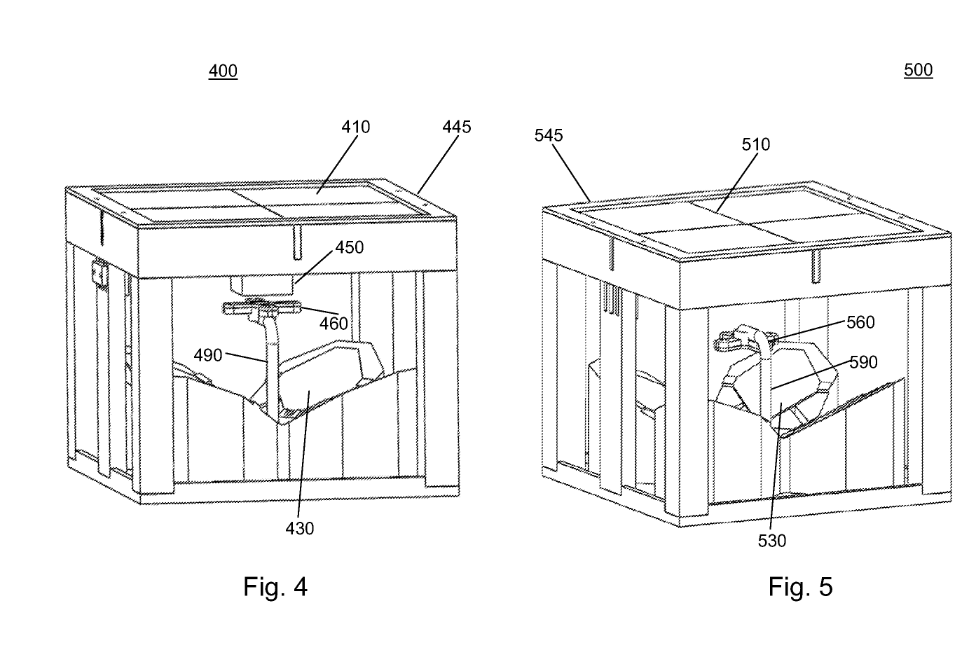

FIG. 4 is a perspective view of a PV device 400, according to an embodiment. An array 410 of light concentrators may be arranged to receive incident light through top frame 445 that may be part of a supporting structure of PV device 400. As explained above, light splitters 430 may reflect a portion of incident light having a particular range of wavelengths. Such reflected light may subsequently be directed to a first solar cell 460 via minor 450. First solar cell 460 may be mounted on a heat pipe 490 to conduct heat away from first solar cell 460, for example. In a particular implementation, an additional benefit provided by heat pipe 490 may include the fact that heat pipe 490 may be configured to avoid blocking incident sunlight by having a relatively narrow profile within PV device 400. Mirror 450 may provide a technique for reducing a height of PV device 400 by folding light reflected from light splitters 430 as the light transits to first solar cell 460. In such a case, first solar cell 460 may comprise an active region facing upward, wherein “upward” is defined as a direction opposite to that of light incident upon array 410.

FIG. 5 is a perspective view of a photovoltaic device 500, according to an embodiment. An array 510 of light concentrators may be arranged to receive incident light through top frame 545 that may be part of a supporting structure of PV device 500. As explained above, light splitters 530 may reflect a portion of incident light having a particular range of wavelengths. Such reflected light may subsequently be directed to a first solar cell 560. In contrast to a configuration described in FIG. 4 for PV device 400, a mirror to redirect light from light splitters 530 to first solar cell 560 need not be present. In such a case, first solar cell 560 may comprise an active region facing downward, wherein “downward” is defined as a direction the same as that of light incident upon array 510. In one implementation, first solar cell 560 may be mounted on a heat pipe 590 to conduct heat away from first solar cell 560, for example. In such an implementation, an additional benefit provided by heat pipe 590 may include the fact that heat pipe 590 may be configured to avoid blocking incident sunlight by having a relatively narrow profile within PV device 500.

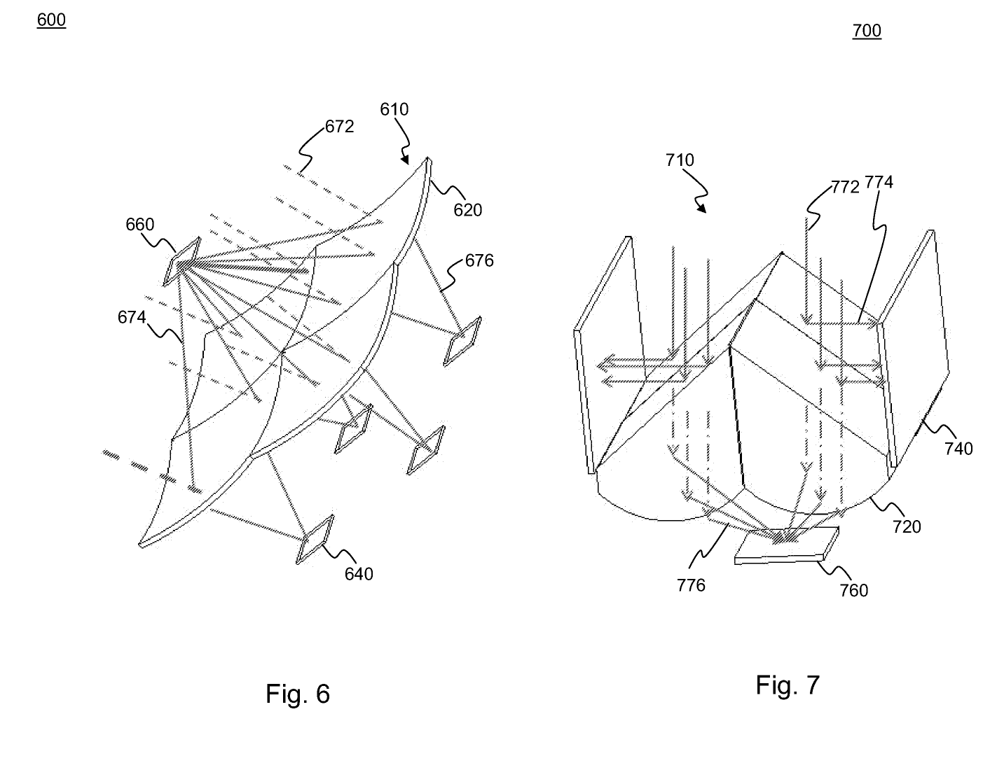

FIG. 6 is a perspective view of a photovoltaic device 600, according to an embodiment. Array 610 may comprise multiple lenses 620 that combine functions of light concentrators and light splitters to focus incident light 672 and selectively reflect and transmit different portions of the light based, at least in part, on wavelength of the light, as explained above. In one implementation, though array 610 is described as comprising multiple lenses, array 610 may comprise a single compound lens (e.g., a single shaped piece of optical material) including different portions that comprise lenses 620. In another implementation, multiple lenses 620 may be physically separate from one another in array 610 or multiple lenses 620 may be combined (e.g., glued) to form array 610. Such lenses may comprise a refractive lens having optical dielectric coatings that transmit or reflect light by constructively and/or destructively combining waves of particular wavelengths of the light. As a result, reflected light 674 may be focused and directed to first solar cell 660 while transmitted light 676 may be focused and directed to second solar cells 640. In an implementation, light 674 reflected from surfaces of multiple lenses 620 may combine at first solar cell 660, which may generate electrical power based, at least in part, on such relatively high intensity combined light. Meanwhile, light 676 transmitted through multiple lenses 620 may focus onto respective second solar cells 640, wherein each such solar cell may correspond to one lens 620, though claimed subject matter is not so limited. For example, in another implementation, every two second solar cells 640 may correspond to one lens 620, and so on. It is to be understood that PV device 600 may comprise additional optical elements such as mirrors to collimate light 672, 674, and/or 676, as well as structural support elements to support such elements of PV device 600. For example, a heat pipe to dissipate heat from first solar cell 660 may be present to physically support first solar cell 660. For another example, a folding mirror, such as mirror 250 may be placed to fold light 674 so that an active region of first solar cell 660 may face upward, wherein “upward” is defined as a direction opposite to that of light incident upon array 610.

FIG. 7 is a perspective view of a photovoltaic device 700, according to an embodiment. Array 710 may comprise multiple lenses 720 that combine functions of light concentrators and light splitters to focus incident light 772 and selectively reflect and transmit different portions of the light based, at least in part, on wavelength of the light, as explained above. In one implementation, though array 710 is described as comprising multiple lenses, array 710 may comprise a single compound lens (e.g., a single shaped piece of optical material) including different portions that comprise lenses 720. In another implementation, multiple lenses 720 may be physically separate from one another in array 710 or multiple lenses 720 may be combined (e.g., glued) to form array 710. Such lenses may comprise a refractive lens having optical coatings that transmit or reflect light as described above. As a result, reflected light 774 may be focused and directed to second solar cells 740 while transmitted light 776 may be focused and directed to first solar cell 760. In an implementation, light 776 transmitted through multiple lenses 720 may combine at first solar cell 760, which may generate electrical power based, at least in part, on such relatively high intensity combined light. Meanwhile, light 774 reflected from surfaces of multiple lenses 720 may focus onto respective second solar cells 740, wherein each such solar cell may correspond to one lens 720, though claimed subject matter is not so limited. For example, in another implementation, every two second solar cells 740 may correspond to one lens 720, and so on. It is to be understood that PV device 700 may comprise additional optical elements such as mirrors to collimate light 772, 774, and/or 776, as well as structural support elements to support such elements of PV device 700. For example, a heat pipe to dissipate heat from first solar cell 760 may be present to physically support first solar cell 760. In one implementation, a bottom portion of a structure or framework to support PV device 700 may comprise a heat sink on which first solar cell 760 may be placed. Of course, details of PV device 700 described above are merely examples of possible configurations, and claimed subject matter is not limited in this respect.

One skilled in the art will realize that a virtually unlimited number of variations to the above descriptions is possible, and that the examples and the accompanying figures are merely to illustrate one or more particular implementations.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. An apparatus comprising:
an array of light concentrators to collect and focus light; and
an array of individual light splitters, said individual light splitters to direct a plurality of components of light including a first component of light directed to one or more second solar cells and respective second components of light directed to a region coincident with a location on a first solar cell.

2. The apparatus of claim 1, wherein said first solar cell is located substantially equally distant to each element of said array of light concentrators.

3. The apparatus of claim 1, wherein said array of light concentrators and said array of light splitters comprise a single integral optical element.

4. The apparatus of claim 1, wherein said location of said first solar cell comprises a portion of a central axis of both said array of light concentrators and said array of light splitters.

5. The apparatus of claim 4, wherein said individual light splitters are tilted at substantially an angle in a range between 60 to 70 degrees from said central axis.

6. The apparatus of claim 1, wherein said location of said first solar cell comprises a focal plane of said array of light concentrators.

7. The apparatus of claim 5, wherein said one or more second solar cells are symmetrically arranged about said central axis.

8. The apparatus of claim 1, wherein said first component of light directed to said one or more second solar cells comprises light reflected from said individual light splitters, and wherein said respective second components of light directed to said region coincident with said location on said first solar cell comprises light transmitted through said individual light splitters.

9. The apparatus of claim 1, wherein said first component of light directed to said one or more second solar cells comprises light transmitted through said individual light splitters, and wherein said respective second components of light directed to said region coincident with said location on said first solar cell comprises light reflected from said individual light splitters.

10. The apparatus of claim 8, wherein said reflected light comprises light having a spectral range different from that of said transmitted light

11. The apparatus of claim 1, wherein said first solar cell is operable in a spectral range different from that of said second solar cells.

12. The apparatus of claim 1, wherein said first solar cell comprises a double-junction solar cell and said one or more second solar cells comprise silicon solar cells.

13. The apparatus of claim 1, wherein said first solar cell is mounted on a thermally-conducting heat pipe.

14. The apparatus of claim 1, further comprising a central supporting structure on which to mount said first solar cell.

15. The apparatus of claim 1, wherein an active region of said first solar cell is positioned to receive said light from a direction substantially opposite to a direction of said light collected by said array of light concentrators.

16. The apparatus of claim 4, wherein said first solar cell is mounted along said central axis in a substantially central region among said array of individual light splitters.

17. A method comprising:
assembling an array of light concentrators to collect light; and
arranging an array of light splitters to:
direct said collected light based, at least in part, on a wavelength of said collected light,
direct a first portion of said collected light from individual light splitters of said array to converge to a region coincident with a location on a first solar cell, and
direct a second portion of said collected light to one or more second solar cells
arranging said first portion of said collected light.
wherein said first solar cell is located substantially equally distant to said array of light concentrators.

18. The method of claim 17, wherein said location of said first solar cell comprises a portion of a central axis of both said array of light concentrators and said array of light splitters.

19. The method of claim 17, wherein said location of said first solar cell comprises a focal plane of said array of light concentrators.

20. The method of claim 18, further comprising arranging said one or more second solar cells about said central axis.

21. The method of claim 17, further comprising positioning an active region of said first solar cell to receive said light from a direction substantially opposite to a direction of said light collected by said array of light concentrators.

22. The method of claim 17, wherein said first portion of collected light comprises light reflected from said individual light splitters, and wherein said second portion of collected light comprises light transmitted through said individual light splitters.

23. The method of claim 17, wherein said first portion of collected light comprises light transmitted through said individual light splitters, and wherein said second portion of collected light comprises light reflected from said individual light splitters.

24. The method of claim 18, wherein said array of light splitters are tilted at substantially an angle in a range between 60 to 70 degrees from said central axis.

25. A method comprising:
collecting and focusing incident light;
providing said collected and focused light to an array of individual light splitters to direct said collected light based, at least in part, on a wavelength of said light;
directing a first portion of said collected light to converge to a region coincident with a location on a first solar cell; and
directing a second portion of said collected light to one or more second solar cells.
wherein said first solar cell is located substantially equally distant to said array of light concentrators.

26. The method of claim 25, wherein said location of said first solar cell comprises a portion of a central axis of said array of light splitters.

27. The method of claim 26, wherein said one or more second solar cells are symmetrically arranged about said central axis.

28. The method of claim 25, wherein said first portion of collected light comprises light reflected from said individual light splitters, and wherein said second portion of collected light comprises light transmitted through said individual light splitters.

29. The method of claim 25, wherein said first portion of collected light comprises light transmitted through said individual light splitters, and wherein said second portion of collected light comprises light reflected from said individual light splitters.

30. The method of claim 29, wherein said reflected light comprises light having a spectral range different from that of said transmitted light

31. The method of claim 26, wherein said array of individual light splitters are tilted at substantially an angle in a range between 60 to 70 degrees from said central axis.
